(19) United States
(12) Patent Application Publication
(10) Pub. No.: US 2007/0092046 A1
(43) Pub. Date: Apr. 26, 2007

(54) Method of reducing interference among wireless network by intentionally violating the communication protocol

(76) Inventor: Hyun Lee, Ladera Ranch, CA (US)

Correspondence Address: Hyun Lee, 21 Thalia St, Ladera Ranch, CA, 92694, US

(21) Appl. No.: 11/585,480

(22) Filed: Oct. 24, 2006

Related U.S. Application Data
(60) Provisional application No. 60/730,151, filed on Oct. 25, 2005.

(51) Int. Cl. H03D 1/04

(52) U.S. Cl. 375/346

(57) ABSTRACT

A way of mitigating the interference among wireless devices that use the same media. This method is based on the assumption that all wireless devices are well-behaved devices in the sense that these devices exhibit the predictable behavior according to the wireless protocol specification. Based on this assumption, this invention utilizes two device behaviors in the UWB protocol to reduce interference among wireless network, and also to meet the DAA (Detect and Avoid) requirement that is mandated by he European Conference of Postal and Telecommunications Administrations (CEPT) and Japan's Ministry of Internal Affairs and Communications (MIC).

### RELATED APPLICATIONS

The present application is a continuation application of U.S. provisional patent application, Ser. No. US60/730,151, filed Oct. 25, 2005, for METHOD OF REDUCING INTERFERENCES AMONG WIRELESS NETWORKS BY INTENTIONALLY VIOLATING HE COMMUNICATION PROTOCOL, by Hyun Lee, included by reference herein and for which benefit of the priority date is hereby claimed.

### FIELD OF THE INVENTION

The present invention relates to the fields of home and personal wireless networking and, more particularly, to Wireless Home Area Networks or Wireless Personal Area Networks that are based on various standard communication protocols.

### BACKGROUND OF THE INVENTION

Unlike the wired network where the communication media is dedicated to a particular network, a multiple network could occupy the same wireless communication media, and they could interfere each other unless there is such an arbitration scheme that controls the accesses of the wireless media among these networks. However, in reality it is near impossible to develop such an arbiter because of the following reasons.

a) Since not all the networks uses the same RF modulation method and the same wireless protocol, an arbiter would need the capability of supporting various modulation methods and a multiple protocol simultaneously

b) Since the arbiter would not be able to identify the sources of all the signals that occupy the same media, the arbiter cannot communicate with all the sources for arbitration. As an example, an arbiter for a Wireless Personal network cannot communicate with the cell tower to arbitrate the cell phone signal

Therefore, in wireless communication, the interference among different networks becomes an issue that brings concerns not only to the wireless network developers but also to the governments that allot the frequency spectrum for the unlicensed use.

In some cases, the interference issue becomes the roadblock for the consumer adoption of the wireless communication technology. For example, the European Conference of Postal and Telecommunications Administrations (CEPT) and Japan's Ministry of Internal Affairs and Communications (MIC) imposed the mandatory requirement that UWB network for personal use cannot interfere with the existing services such as cordless telephone or the 4 G cellular phone technologies.

Therefore, it is critical to develop a general solution to address the interference issue in the wireless network.

There are generally two different approaches that are commonly used to handle the interference issues. The first approach is embedding the interference avoiding mechanism in the communication protocol. The second approach is using the Physical layer device (PHY) to detect other signals in the media, and take an action to avoid the collision with other signals.

Some examples of the interference avoiding communication protocols are: Assigning certain time slots to certain devices in the network, which is referred to Time Division Multiple Access (TDMA); assigning certain frequency bands to certain devices in the network, which is referred to as Frequency Division Multiple Access (FDMA); and assigning certain code space to certain devices in the network, which is referred as Code Division Multiple Access (CDMA).

Beside these techniques, there are advanced techniques that combine more than one of these basic techniques. Some of the advanced techniques are Multiband Orthogonal Frequency Division Multiplexing (MB-OFDM) and Direct Sequence Spread Spectrum (DSSS) etc.

The simplest method of the second approach is to hold off the transmitters until there is no other signal is in the media, for example, IEEE 802.3.

The other method is to detect the interference during transmitting the data. When a transmitter detects interference, it stops transmit assuming the other transmitter would do the same. Once all transmitters stop, then the device with the leas amount of wait period starts to transmit. However, this approach only works if the strengths of interfering signals are approximately the same. Otherwise, the strongest signal dominates the media, and other interfering signals would be discarded as noise.

The shortcoming of the first method is that this commonly used method to address the interference issue generally works well when all the devices that use the same media are within the same network, and they share the same communication protocol. However, if these devices use different protocols, none of the currently employed interference avoidance methods work. For example, a group of device whose media access is governed by a particular arbiter would not work well with another group of devices whose media access is governed by some other arbiter. Furthermore, the interference issue presents another degree of challenge when a communication media is occupied with devices that use different RF modulation schemes, such as broad band vs. narrow band vs. ultra wide band, etc. In this case since the ultra wide band antenna cannot detect the broadband signals, the devices could not recognize that they are interfering with each other.

The shortcoming of the second method is that, unlike wired network, a wireless transmitter cannot recognize any over the air collision with other signals unless a receiver accompanies a transmitter to listen to the RF signal and check if the receiving signal is the same as the transmit signal. Using a receiver-transmitter pair to detect collisions works well in the wired Ethernet world. However, this method (using a receiver-transmitter pair) presents substantial issues in the wireless communication networks, such as power consumption, physical implementation of dual antenna with duplicated baseband controllers, additional circuitry to compare the signals, etc. Furthermore, if the strength of other signals at the receiver antenna were much lower than the transmitting signal strength, the receiver would not be able to detect the interfering signal. Thus, the transmitted signal continuously interferes with other signals.

Due to the issues associated with the receiver-transmitter pair solution, some wireless PHY manufactures do not adopt this method to address the wireless signal interference problem, such as the latest mandate imposed by the European Conference of Postal and Telecommunications Administrations (CEPT) and Japan's Ministry of Internal Affairs and Communications (MIC). To satisfy this mandate, wireless PHY manufactures developed a narrowband detecting method, in which a master UWB device performs a narrowband signal existence test prior to starting the service, and continuously performs the same test when the master UWB device periodically stops the broadband operations of all slave UWB devices. The idea is that, if the master UWB device detects a signal while it stops all the broadband operations, it assumes it is interfering with a narrowband operation, and moves to another channel along with all slave UWB devices. This method, the master UWB and slave UWB concept, introduces a foreign concept to the UWB. This method may only work for WUSB, where the WUSB host is able to halt broadband transmission of all WUSB devices. However, in a peer-to-peer communication network, this method is likely to fail since all UWB devices in the network schedule their own transmission times, and no one UWB device can force another UWB device to hold its transmission. One other issue with this method is that it does not present a solution when the actual interference is not from a distant narrowband device, but from a UWB device in a neighboring UWB network. In this case, this method may cause the UWB devices in both networks to move to the same channel synchronously, and is therefore likely to produce a very similar interference problem.

It is therefore an object of the invention to detect inteferences among wireless devices

It is another object of the invention to provide a method to identify the source of the interference.

It is another object of the invention to provide a method to notify the devices in the network of the presence of the exsting service

It is another object of the invention to provide a way of halting all other UWB signal activities so that the existing service is not interfered.

### SUMMARY OF THE INVENTION

In accordance with the present invention, there is provided a way of mitigating the interference among wireless devices that use the same media. This method is based on the assumption that all wireless devices are well-behaved devices in the sense that these devices exhibit the predictable behavior according to the wireless protocol specification. Based on this assumption, this invention utilizes two device behaviors in the UWB protocol to reduce interference among wireless network, and also to meet the DAA (Detect and Avoid) requirement that is mandated by he European Conference of Postal and Telecommunications Administrations (CEPT) and Japan's Ministry of Internal Affairs and Communications (MIC).

### BRIEF DESCRIPTION OF THE DRAWINGS

A complete understanding of the present invention may be obtained by reference to the accompanying drawings, when considered in conjunction with the subsequent, detailed description, in which:

FIG. 1 is a state diagram to detect and avoid interference with narrow/broad band and other uwb signals.

For purposes of clarity and brevity, like elements and components will bear the same designations and numbering throughout the Figures.

### DESCRIPTION OF THE PREFERRED EMBODIMENT

This method is based on the assumption that all wireless devices are well-behaved devices in the sense that these devices exhibit the predictable behavior according to the wireless protocol specification. Based on this assumption, this invention utilizes two device behaviors in the UWB protocol to reduce interference among wireless network, and also to meet the DAA (Detect and Avoid) requirement that is mandated by CEPT and MIC.

The behaviors that this invention utilizes are:

1) A device does not transmit if its transmission space is already occupied.

2) If a device cannot make bandwidth reservation, or cannot find an open bandwidth, it moves to another channel or does not initiate transmission.

The first device behavior is consistent among all wireless devices. The transmission space is a code space for CDMA, a time slot for TDMA, a frequency space for FDMA, or a channel for OFDM. The second device behavior also is consistent among all wired and all wireless devices. The bandwidth is the means of transferring its data. The bandwidth is an unoccupied code space for CDMA, the number of time slots for TDMA, unoccupied frequency for FDMA, and the number of time slot in a given channel for OFDM.

The means of utilizing these behaviors by violating two requirements in the wireless communication protocol.

a) fairness policy.

b) guard band time requirement.

Any communication network, wired or wireless, generally imposes these two requirements. The first requirement is to provide acceptable QoS to all devices in the network. The second requirement is to prevent any signal collisions between two transmitters by requiring a quiet time between the end of transmission from one device and the start of transmission from another device.

Therefore, the interference mitigation method presented in this application is not limited to a particular wireless communication network.

The main idea of this invention is that by depriving the transmission capability of wireless device by violating the agreed protocol, it causes the wireless devices to move into an alternative communication space. The communication space is the same as the transmission space.

Applying this invention to WiMedia, the two device behaviors are defined as:

1) A device does not transmit during any unreserved time slots if it detects a signal at the beginning of the time slot.

2) If a device cannot make time slot reservation, or cannot transmit during any PCA (prioritized contention access) time slots, it moves to another channel.

In WiMedia, there is a device that starts a beacon, which is the one that arbitrates the time slots in Super frames. To induce these two device behaviors (1 and 2 at above) from another device, the beacon-arbitrating device performs the following tasks:

I. Always monitors for a signal during the guard band period. If it detects a signal during the guard band time, it checks to see if the signal originated from its own cluster.

II. Always monitors for a signal during unreserved time slots; if it detects a signal at the beginning of the unreserved time slot, it checks to see if the signal originated from its own cluster.

III. Randomly reserve a time slot to monitors for a signal. If it detects a signal during its reserved time slot, it checks to see if the signal originated from its own cluster.

In I-III, if the signal originated from its own cluster, the beacon-arbitrating device identifies the protocol-violating device, and blocks any transmission from the violating device by denying all time slot reservation requests from the violating device, and then starts occupying all unreserved (and PCA) time slots before the end of the guard band period. By occupying the unreserved (and PCA) time slots before the end of the guard band period, the beacon-arbitrating device violates the WiMedia protocol; however, it effectively deprives any chance that the violating device can transmit any data. Thus, the beacon-arbitrating device utilizes the device behaviors (1 and 2) to remove the violating device from its network. After the beacon-arbitrating device removes the violating device from its network, it performs the tasks I-III again.

However, in I-III, if the signal did not originate from its own cluster, the beacon-arbitrating device stops its own transmission, and looks for all neighboring beacon packets to find out if the signal is originated from another WiMedia cluster. If the signal is from a neighboring WiMedia cluster, it does not assign the time slots that are occupied by a device belonging to the neighboring WiMedia cluster.

Finally, in I-III, if the signal did not originate from another WiMedia cluster, then the beacon-arbitrating device decides that it is interfering the existing services, and blocks all transmissions from all devices in the cluster by occupying all beacon slots with dummy device ID's. This violates the fairness policy, but it effectively causes all devices to move to an alternate channel.

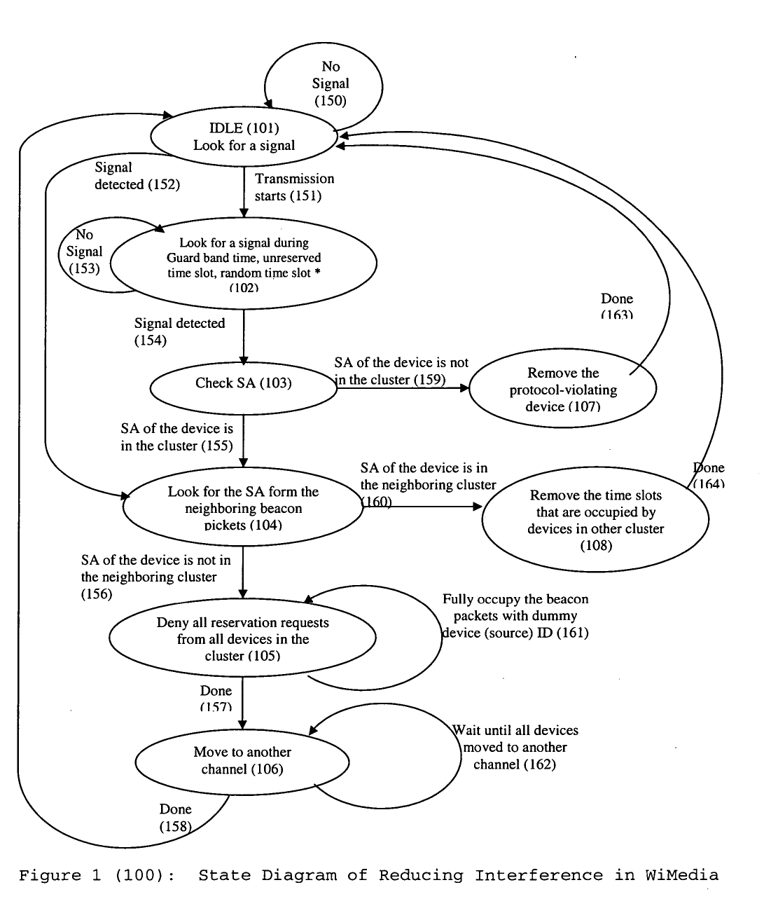

FIG. 1 (100) shows the state diagram of detecting and avoiding interference with the narrow band signal, and avoiding interference with other WiMedia signals.

During the IDLE 101 (101) state (no device in the cluster is transmitting or receiving), the beacon-arbitrating device looks for a signal (151). If it sees a signal, it monitors the neighbor beacon packets (104) to decide if the signal is from a neighbor cluster (160) or not (156).

From the IDLE 101 (101) state, when any device in the cluster starts to transmit (151), the beacon-arbitrating device moves into the next state (102).

While the beacon-arbitrating device is in (102) state, if it sees a signal (154), it checks to see if a device in the cluster transmitted the signal (159). If this is the case, the beacon-arbitrating device isolates the protocol-violating device (107), and goes back (163) to look for a signal (states 101, and 102). However, if the signal is not from its own cluster (155), the beacon-arbitrating device expends its scope in search of the originator device in its neighbor clusters (104).

If the signal is from its neighbor clusters (160), the beacon-arbitrating device removes the time slots that are occupied by its neighboring cluster (108), and goes back (164) to look for a signal (states 101 and 102). If the signal is not from any of its neighbor cluster (156), the beacon-arbitrating device decides that it is interfering existing services, and blocks all transmissions from all devices in its cluster (105). When the blocking is completed, all devices in the cluster move to another channel (106), including the beacon-arbitrating device according to the expected behavior of devices in a WiMedia cluster.

After all the devices in the cluster move into alternate channel, the process in FIG. 1 (100) restarts.

Therefore, based on this invention, without introducing a foreign concept such as the master/slave UWB devices concept, the beacon-arbitrating device not only removes interferences among various WiMedia clusters,-but it also provides the most efficient DAA (Detect and Avoid) function that is mandated by CEPT and MIC. Furthermore, this invention checks to see if the device that causes the interference is in a neighboring broadband device (104), and prevents any unnecessary channel changes by making the blind assumption that the interfering signal is a narrowband (3 G/4 G) signal.

Since other modifications and changes varied to fit particular operating requirements and environments will be apparent to those skilled in the art, the invention is not considered limited to the example chosen for purposes of disclosure, and covers all changes and modifications which do not constitute departures from the true spirit and scope of this invention.

Having thus described the invention, what is desired to be protected by Letters Patent is presented in the subsequently appended claims.

What is claimed is:

1. A method of reducing interference among wireless network by intentionally violating the communication protocol for minimizing the interference among various wireless networks such as wpan (wireless personal area networks), whan (wireless home area networks), and existing narrowband services (ex. 3 g/4 g), comprising:
means for during the idle state, the master, the host, or the beaconing devices continuously checks for the existence of any signals;
means for indicating that, after the start of the network activity, the master (or the host, or the beacon master) continuusly search for protocol violators by monitoring the existance of any signals during the quite time;
means for indicating that, if there is signal activities during the quite time, the master (or the host, or the beacon master) determines if the source of these signals are from the devices that belong to its network;
means for checking if the source of the signal is from the neighboring network;
means for indicating that, if the master (or the host, or the beacon master) does not recognize the source address, it interrupts the network by denying network accesses from all devices in the network;
means for the master, the host, or the beacon master instructs the devices in the network to synchronously move to another channel;
means for if the sa identifies that the protocol violating device is within the cluster, the the master (or the host, or the beaconing device) denies network access from the violator;
means for removing the time slots that are occupied by the neighboring clusters;
means for indicating that the network initialization is completed with the beacon packet, and starting the first packet transmit;
means for moving from the state of waiting for any signal to the sate where the network host starts analyzing the signals;
means for moving to the state to process the packet whose target device is not in the cluster;
means for recognizing that the host cannot identify the packet or the signal;
means for representing the completion of blocking the channel access requests from all the devices in the network so that the network is ready to move to another channel, to avoid any interference with un-identified signals;
means for initializing the action of removing the device, which violates the network protocol, from the network;
means for the host to notice that the packet belongs to the neighboring cluster;
means for the host to continuously occupying the time slots with dummy id to block any accesses from any device in the cluster; and
means for holding the state transmission until the current channel change operation is complete.

2. The method of reducing interference among wireless network by intentionally violating the communication protocol in accordance with claim 1, wherein said means for during the idle state, the master, the host, or the beaconing devices continuously checks for the existence of any signals comprises a state, idle.

3. The method of reducing interference among wireless network by intentionally violating the communication protocol in accordance with claim 1, wherein said means for indicating that, after the start of the network activity, the master (or the host, or the beacon master) continuusly search for protocol violators by monitoring the existance of any signals during the quite time comprises a function, look for protocol violators.

4. The method of reducing interference among wireless network by intentionally violating the communication protocol in accordance with claim 1, wherein said means for indicating that, if there is signal activities during the quite time, the master (or the host, or the beacon master) determines if the source of these signals are from the devices that belong to its network comprises a function, check sa.

5. The method of reducing interference among wireless network by intentionally violating the communication protocol in accordance with claim 1, wherein said means for checking if the source of the signal is from the neighboring network comprises a function, check sa from the neighboring beacon.

6. The method of reducing interference among wireless network by intentionally violating the communication protocol in accordance with claim 1, wherein said means for indicating that, if the master (or the host, or the beacon master) does not recognize the source address, it interrupts the network by denying network accesses from all devices in the network comprises a function, deny all reservation requests from all devices in the cluster.

7. The method of reducing interference among wireless network by intentionally violating the communication protocol in accordance with claim 1, wherein said means for if the sa identifies that the protocol violating device is within the cluster, the the master (or the host, or the beaconing device) denies network access from the violator comprises a function, removing violator.

8. The method of reducing interference among wireless network by intentionally violating the communication protocol in accordance with claim 1, wherein said means for removing the time slots that are occupied by the neighboring clusters comprises a function, remove time slots.

9. The method of reducing interference among wireless network by intentionally violating the communication protocol in accordance with claim 1, wherein said means for moving from the state of waiting for any signal to the sate where the network host starts analyzing the signals comprises an observation point, signal detected.

10. The method of reducing interference among wireless network by intentionally violating the communication protocol in accordance with claim 1, wherein said means for moving to the state to process the packet whose target device is not in the cluster comprises a decision point, sa not in cluster.

11. The method of reducing interference among wireless network by intentionally violating the communication protocol in accordance with claim 1, wherein said means for recognizing that the host cannot identify the packet or the signal comprises a decision point, sa not in neighboring cluster.

12. The method of reducing interference among wireless network by intentionally violating the communication protocol in accordance with claim 1, wherein said means for representing the completion of blocking the channel access requests from all the devices in the network so that the network is ready to move to another channel, to avoid any interference with un-identified signals comprises a task completion, deny access done.

13. The method of reducing interference among wireless network by intentionally violating the communication protocol in accordance with claim 1, wherein said means for initializing the action of removing the device, which violates the network protocol, from the network comprises a decision point, violator sa in cluster.

14. The method of reducing interference among wireless network by intentionally violating the communication protocol in accordance with claim 1, wherein said means for the host to notice that the packet belongs to the neighboring cluster comprises a decision point, sa in the neighboring cluster.

15. The method of reducing interference among wireless network by intentionally violating the communication protocol in accordance with claim 1, wherein said means for the host to continuously occupying the time slots with dummy id to block any accesses from any device in the cluster comprises a function, fully occupy the channel.

16. A method of reducing interference among wireless network by intentionally violating the communication protocol for minimizing the interference among various wireless networks such as wpan (wireless personal area networks), whan (wireless home area networks), and existing narrowband services (ex. 3 g/4 g), comprising:
a state, idle, for during the idle state, the master, the host, or the beaconing devices continuously checks for the existence of any signals;
a function, look for protocol violators, for indicating that, after the start of the network activity, the master (or the host, or the beacon master) continuusly search for protocol violators by monitoring the existance of any signals during the quite time;
a function, check sa, for indicating that, if there is signal activities during the quite time, the master (or the host, or the beacon master) determines if the source of these signals are from the devices that belong to its network;
a function, check sa from the neighboring beacon, for checking if the source of the signal is from the neighboring network;
a function, deny all reservation requests from all devices in the cluster, for indicating that, if the master (or the host, or the beacon master) does not recognize the source address, it interrupts the network by denying network accesses from all devices in the network;
a function, move to antoher channel, for the master, the host, or the beacon master instructs the devices in the network to synchronously move to another channel;
a function, removing violator, for if the sa identifies that the protocol violating device is within the cluster, the the master (or the host, or the beaconing device) denies network access from the violator;
a function, remove time slots, for removing the time slots that are occupied by the neighboring clusters;
a function, transmission starts, for indicating that the network initialization is completed with the beacon packet, and starting the first packet transmit;
an observation point, signal detected, for moving from the state of waiting for any signal to the sate where the network host starts analyzing the signals;
a decision point, sa not in cluster, for moving to the state to process the packet whose target device is not in the cluster;
a decision point, sa not in neighboring cluster, for recognizing that the host cannot identify the packet or the signal;
a task completion, deny access done, for representing the completion of blocking the channel access requests from all the devices in the network so that the network is ready to move to another channel, to avoid any interference with un-identified signals;
a decision point, violator sa in cluster, for initializing the action of removing the device, which violates the network protocol, from the network;
a decision point, sa in the neighboring cluster, for the host to notice that the packet belongs to the neighboring cluster;
a function, fully occupy the channel, for the host to continuously occupying the time slots with dummy id to block any accesses from any device in the cluster; and
an observation point, wait for channel change commpletion, for holding the state transmission until the current channel change operation is complete.

17. The method of reducing interference among wireless network by intentionally violating the communication protocol as recited in claim 16, further comprising:
an observation point, signal exist, for representing the case when the network detects signal prior to initiating any transaction.

18. The method of reducing interference among wireless network by intentionally violating the communication protocol as recited in claim 16, further comprising:
an observation point, wait for signal, for indicating the waiting period whle the host is waiting for any response from any device in the network.

19. The method of reducing interference among wireless network by intentionally violating the communication protocol as recited in claim 16, further comprising:
a completion of the operation, done, for the network to restart the daa operation.

20. A method of reducing interference among wireless network by intentionally violating the communication protocol for minimizing the interference among various wireless networks such as wpan (wireless personal area networks), whan (wireless home area networks), and existing narrowband services (ex. 3 g/4 g), comprising:
a state, idle, for during the idle state, the master, the host, or the beaconing devices continuously checks for the existence of any signals;
a function, look for protocol violators, for indicating that, after the start of the network activity, the master (or the host, or the beacon master) continuusly search for protocol violators by monitoring the existance of any signals during the quite time;
a function, check sa, for indicating that, if there is signal activities during the quite time, the master (or the host, or the beacon master) determines if the source of these signals are from the devices that belong to its network;
a function, check sa from the neighboring beacon, for checking if the source of the signal is from the neighboring network;
a function, deny all reservation requests from all devices in the cluster, for indicating that, if the master (or the host, or the beacon master) does not recognize the source address, it interrupts the network by denying network accesses from all devices in the network;
a function, move to antoher channel, for the master, the host, or the beacon master instructs the devices in the network to synchronously move to another channel;
a function, removing violator, for if the sa identifies that the protocol violating device is within the cluster, the the master (or the host, or the beaconing device) denies network access from the violator;
a function, remove time slots, for removing the time slots that are occupied by the neighboring clusters;
a function, transmission starts, for indicating that the network initialization is completed with the beacon packet, and starting the first packet transmit;
an observation point, signal exist, for representing the case when the network detects signal prior to initiating any transaction;
an observation point, wait for signal, for indicating the waiting period whle the host is waiting for any response from any device in the network;
an observation point, signal detected, for moving from the state of waiting for any signal to the sate where the network host starts analyzing the signals;
a decision point, sa not in cluster, for moving to the state to process the packet whose target device is not in the cluster;
a decision point, sa not in neighboring cluster, for recognizing that the host cannot identify the packet or the signal;
a task completion, deny access done, for representing the completion of blocking the channel access requests from all the devices in the network so that the network is ready to move to another channel, to avoid any interference with un-identified signals;
a completion of the operation, done, for the network to restart the daa operation;
a decision point, violator sa in cluster, for initializing the action of removing the device, which violates the network protocol, from the network;
a decision point, sa in the neighboring cluster, for the host to notice that the packet belongs to the neighboring cluster;
a function, fully occupy the channel, for the host to continuously occupying the time slots with dummy id to block any accesses from any device in the cluster; and
an observation point, wait for channel change commpletion, for holding the state transmission until the current channel change operation is complete.
